(19) United States
(12) Patent Application Publication
(10) Pub. No.: US 2013/0220406 A1
(43) Pub. Date: Aug. 29, 2013

(54) VERTICAL JUNCTION SOLAR CELL STRUCTURE AND METHOD

(71) Applicants: Stephen DAY, Chipping Norton (GB); James Andrew Robert DIMMOCK, Oxford (GB); Matthias KAUER, Oxford (GB)

(72) Inventors: Stephen DAY, Chipping Norton (GB); James Andrew Robert DIMMOCK, Oxford (GB); Matthias KAUER, Oxford (GB)

(73) Assignee: SHARP KABUSHIKI KAISHA, Osaka (JP)

(21) Appl. No.: 13/406,087

(22) Filed: Feb. 27, 2012

(51) Int. Cl. H01L 31/0352; H01L 31/18; B82Y 99/00

(52) U.S. Cl. 136/255; 438/98; 977/948; 257/E31.124

(57) ABSTRACT

A non-close-packed vertical junction photovoltaic device includes a substrate, a two-dimensional array of elongate nanostructures extending substantially perpendicularly from a surface of the substrate, and a thin film solar cell disposed over the nanostructures such that the thin film solar cell substantially conforms to the topography of the nanostructures. An average separation of nearest neighbor solar cell coated nanostructures is greater than zero and less than a vacuum wavelength of light corresponding to a band gap of absorption. The thin film solar cell may include an active region that conforms to the elongate nanostructures, a first electrode that conforms to a surface of the active region, and a second electrode. A separation of opposing outer surfaces of the first electrode extending along adjacent elongate nanostructures is greater than zero and less than the vacuum wavelength of the light corresponding to the band gap of the active region.

### TECHNICAL FIELD

This invention relates to solar cells and, more particularly, to a device structure and method of making and incorporating a vertical junction for achieving higher efficiency in a solar cell.

### BACKGROUND ART

A solar cell typically includes two contact electrodes and at least one active region including a semiconductor junction that provides photovoltaic action. For example, the semiconductor junction(s) may include a Schottky junction, a p-n junction, or a p-i-n junction. Free charge carriers generated by the absorption of photons in the active region are transported under the influence of an internal potential gradient provided by the junction to the contacts where they are collected and used to power an external circuit. For a solar cell to operate efficiently, at least the following is desired:
1. The absorber material in the active region(s) should absorb as many incident photons as possible resulting in the generation of pairs of oppositely charged free carriers. In order to maximize transmission of light to the active region it is necessary to minimize reflection and absorption losses due to the layer interfaces and other layers in the cell. Light absorption in the active region can be enhanced by maximizing the optical path length of light in the active region and by using materials with large absorption coefficients over the spectral wavelength range required.
2. Charge carriers must be extracted to the electrical contacts before they recombine. The carrier extraction, or collection, efficiency depends on characteristics such as the carrier lifetime, mobility, and the path lengthcarriers must travel before they are collected by the contact electrodes. Efficient carrier extraction can be achieved by maximizing the carrier lifetime and mobility, and by minimizing the distance between the electrodes.

Typically, solar cells include a plurality of two-dimensional layers including at least a first electrode, an active region and a second electrode. Photons absorbed inside the active region generate carriers that must travel to their respective electrode without recombining along a path parallel to that of the original photon direction. The probability of a photon being absorbed increases with the path length traveled by the photon inside the active region. However, the probability of the generated carriers recombining also increases with their path length inside the active region. Thus, greater absorption typically warrants a thicker junction to increase the optical path length and hence the absorption, while for greater carrier extraction it is preferable to use a thinner junction to minimize carrier recombination. Balancing of these factors compromises the efficiency of the solar cell.

The construction of the solar cell is designed to accept and absorb as much incident light as possible for maximum efficiency. For maximum efficiency, the incident light direction is preferred to be normal to the plane of the cell. At least one of the contact electrode layers, known as the front contact, must allow the incident light to pass to the active region. For example, this is achieved if the contact electrode layer is patterned so that regions within the layer have no electrode material. Alternatively, the electrode material may be transparent to light over the spectral response range of the cell.

One type of known solar cell is a thin film solar cell. Conventional thin film solar cells include a plurality of thin layers (or films) of materials, typically 1 nm-10 um in thickness, disposed sequentially (layer-by-layer) on a supporting substrate. The thin film stack typically includes at least two conducting layers, and at least one light absorbing layer. Thin film materials offer technical and commercial advantages over conventional bulk or epitaxially formed materials, including the ability to use a wide variety of material systems, reduced material usage, and compatibility with large area form factors. A review of thin film solar cell technology, including their advantages, can be found in the paper by K. L Chopra et al., “Thin Film Solar Cells: An Overview”, Prog. Photovolt. Res. Appl., 2004, vol 12, pp 69-92, dated Dec. 13, 2003.

Typically, the quality of thin film materials is lower than crystalline bulk or epitaxially grown materials. As a result, the carrier extraction length is significantly reduced. For example, the absorption depth of hydrogenated amorphous silicon (a-Si:H) in a p-i-n a-Si:H thin film solar cell is ˜1 um, while the carrier extraction length is ˜100 nm. These competing optical and electronic length scales mean that the efficiency of the solar cell is compromised by selection of an active layer thickness that is compatible with both absorption and extraction.

Several methods have been described to address the challenges of light management and carrier extraction in thin film solar cells where there are competing length scales:

One approach uses a roughened substrate surface which scatters, or randomizes, the direction of reflected light [see J. Krc et al., “Analysis of light scattering in a-Si:H-based solar cells with rough interfaces”, Solar Energy Materials and Solar Cells, 2002, 74, 401-406]. Since obliquely reflected light can undergo total internal reflection, a perfectly randomizing surface produces an ideal optical path length enhancement factor of 4n² [see E. Yablonovitch, “Statistical ray optics”, J. Opt. Soc. Am., July 1982. Vo. 72, 899-097]. In addition, reflection of light entering the cell is reduced due to refractive index grading at the roughened top surface of the solar cell. The ideal enhancement factor for hydrogenated amorphous silicon (a-Si:H) is ˜50, although enhancement factors of ˜10 have been achieved in real cells. This enables thinner films to be used.

A second approach is to use multiple junctions. Multi-junction solar cells include at least two semiconductor junctions that provide photovoltaic action. Each junction operates in a different wavelength range of the incident light spectrum. The junctions are designed to operate together more efficiently than can be achieved by using only a single junction. Multi-junction cells are typically optically and electrically connected in series by forming multiple active regions sequentially on top of one another such that wavelengths of light weakly or not absorbed by the first junction are transmitted to the second junction and so on [Meier et al., “High Efficiency Amorphous and “Micromorph” Silicon Solar Cells, WCPEC, May 2003]. In this way, each junction can be thinner thereby increasing the carrier collection efficiency. However, a number of practical constraints mean that it is challenging to fully exploit their potential. For example:
The photocurrent generated by each junction should preferably be substantially similar—so called “current matched”. This requires excellent control of the film thickness uniformity that is difficult to achieve over large areas.
Fine control over the material morphology and composition required to tune the band gap of additional layers in multi-junction cells. It is commonly necessary to reduce the deposition rate with a consequential impact on throughput.
Each junction must be connected by a tunnel-junction to prevent the formation of an opposing photo-voltage at the interface between the junctions, which would reduce the open circuit voltage. The tunnel junction should be of sufficiently low resistance so as not to adversely affect the fill factor of the cell. These criteria require the formation of an abrupt junction between high-quality, heavily doped n- and p-type materials.

A third approach is characterized by the use of vertical, and commonly, elongated nanostructures within the solar cells to enhance both light absorption and carrier collection. In the examples described hereafter a nanostructured substrate including an array of substantially vertical elongated nanostructures is first formed. Subsequently, at least one semiconducting and one conducting layer are disposed over the nanostructured substrate such that they substantially conform to, or substantially fill the volume between, the nanostructures.

Zhu et al. (“Nanodome Solar Cells with Efficient Light Management and Self-Cleaning”, Nano Lett. 2010, 10, 1979-1984) describe the use of nanodome surface features formed by patterning the substrate with low aspect ratio nanocones prior the thin film deposition. The thin film disposed on the substrate conforms to the nanocones. In this way a graded refractive index is created between the cell and the air interface resulting in antireflection and light trapping properties over a broad spectral range and a wide set of incident angles.

Zhang et al., U.S. Pat. No. 7,635,600, issued on Dec. 22, 2009, discloses a photovoltaic structure and method of forming comprising a bottom conductive nanowire array electrode with a plurality of doped semiconductor layers, and lastly a second electrode disposed over the nanowire array electrode. The first and second semiconductor layers may form a p-n junction and can, for example, be a conductive polymer or inorganic material.

Lang et al., GB Patent Application No. 2462108, published on Jan. 27, 2010, describes a method of growing solar cells on a nanostructured surface of a substrate where the thickness of a conformal layer or layers is at least half the average spacing of the structures; and at least one of the height of the structures, the average spacing of the structures and the size of the smallest dimension of the structures is set so as to provide an enhanced growth rate for each conformal layer compared to the growth rate over a planar substrate. The length h of the nanostructures satisfies the relationship xh>=d where x is the degree of conformality of the thin film and d is the minimum thickness required to fill the volume between the nanostructures. A further set of nanostructures may be interlaced with the nanostructures on the substrate and used as electrodes in a photovoltaic device structure.

Korevaar et al., U.S. Pat. No. 7,893,348, issued on Feb. 22, 2011, describes a photovoltaic device comprising a plurality of substantially vertical elongated silicon nanostructures on a substrate; a first and second conformal amorphous silicon layers disposed on the nanostructures; a conductive material layer disposed on the second conformal layer; and top and bottom contacts in electrical contact with the conductive material and the plurality of nanostructures respectively. The nanostructures form part of the semiconductor junction in the active region. For example, when n-doped the nanostructures form the n-type region of a p-i-n solar cell. The intrinsic and p-type regions are provided by the first and second conformal amorphous silicon layers respectively. The elongated nanostructures enhance the performance of the photovoltaic device by increasing charge collection due to the nanoscale proximity to the film for charge separation.

Kempa et al., US Patent Application No. 2009/0007956A1, published on Jan. 8, 2009, describes a photovoltaic device including a plurality of solar cells. Each solar cell of the plurality includes a first electrode preferably comprising an electrically conducting nanorod, a second electrode which is shared with at least one adjacent solar cell, and a photovoltaic material located between and in electrical contact with the first and second electrodes. The thickness of the second electrode in a direction from one solar cell to an adjacent solar cell is less than the optical skin depth of the second electrode material, and a separation between the first electrodes of adjacent solar cells is less than a peak wavelength of incident radiation. Each semiconductor thin film of the photovoltaic material may have a thickness of about 5 to about 20 nm.

Naughton et al., “Efficient nanocoax-based solar cells”, Phys. Status. Solidi, 4 (7), 181 (June 2010) teaches that high areal density nanostructures (ideally resulting in the formation of a close-packed thin film coated structure) are preferred to maximize the solar cell efficiency. Fabrication of close-packed nanostructured solar cells by disposing thin films over a high density array of elongated nanostructures is extremely challenging using deposition techniques commonly employed for the manufacture of thin film solar cells, for example, plasma enhanced chemical vapor deposition and physical vapor deposition such as sputter deposition. These techniques do not exhibit sufficient deposition comformality, which results in the inclusion of voids within the film.

Additional variations of photovoltaic structures are described in each of the following:
Tsakalakos et al., “Silicon nanowire solar cells”, Appl. Phys. Lett., 91, 233117 (2007).
Yu et al., “Fundamental limit of nanophotonic light trapping in solar cells”, PNAS, 107 (41)17491 (October 2010).
Kelzenberg et al., “Enhanced absorption and carrier collection in wire arrays for photovoltaic applications”, Nat. Mater, 9, 239 (February 2010).
Vanecek et al., “Nanostructured three-dimensional thin film silicon solar cells with very high efficiency potential”, Appl. Phys. Lett., 98, 163503 (April 2011).

FIG. 1 exemplifies a conventional configuration of thin film solar cells. FIG. FIG. 1 schematically shows an example of a conventional horizontal junction solar cell in which the layers of a first electrode 11, second electrode 12 and active region 13 lie substantially in the plane parallel to that of a substrate 10. Electron 16 and hole 17 are charge carriers generated by an absorption event 15 that migrate towards and are collected by respectively the first electrode 11 and second electrode 12 layer or discrete region in contact with the active layer 13. In this design, the length scales 18 over which photons are absorbed and carriers are extracted are parallel and limited by a common dimension, that is, the thickness 19 of the active region 13 in the cell.

For example, if a photon is absorbed inside the active region, each of the generated carriers must travel to its respective electrode without recombining along a path parallel to that of the original photon direction. The probability of a photon being absorbed increases with the path length traveled by the photon inside the active region. However, the probability of the generated carriers recombining also increases with their path length inside the active region. Thus, greater absorption requires a thicker junction to increase the optical path length and hence the absorption, while for greater extraction it is preferable to use a thinner junction to minimize carrier recombination. Balancing of these factors compromises the performance of the solar cell.

### SUMMARY OF INVENTION

An object of the present invention is a nanostructured solar cell design and method of forming that addresses the technical problems of achieving both efficient light absorption and efficient carrier extraction in thin film solar cells, while enabling its manufacture using common thin film solar cell production processes and equipment.

The present invention discloses a nanostructured thin film solar cell structure incorporating a vertical junction with a non-close-packed arrangement that is compatible with conventional thin film deposition and enables higher power conversion efficiency than the equivalent close-packed design.

The vertical junction nanostructured solar cell of the present invention is formed on a nanostructured substrate comprising a two-dimensional array of substantially vertical elongate nanostructures where the average pitch of the elongate nanostructures is in a range that is greater than that required to form a close-packed structure but less than the wavelength of light corresponding to the lowest band gap of the active region of the solar cell.

More specifically, the present invention exploits the combination of efficient light trapping and uniform carrier generation that can be achieved in non-close packed arrangement to achieve the technical effects of maximizing both the short circuit current density Jsc and open circuit voltage Voc of the cell. For example, the reflectivity of a cell in accordance with the present invention depends on the average pitch of the nanostructures and may include one or more minima. In addition, the effective optical density of a cell in accordance with the present invention depends on the average pitch of the nanostructures and determines both the carrier concentration gradient extending along the length of the nanostructures and total absorption of the cell. The combination of these effects means that within the claimed range of average pitch there exists at least one preferred or optimum average pitch that affords higher efficiency and is compatible with thin film fabrication.

As used in the current application, the following definitions apply:

The phrase nanostructured solar cell refers to a solar cell that includes a substrate, and formed on the substrate is a two-dimensional array of elongate nanostructures extending substantially normal to the plane of a surface of the substrate.

The phrase vertical junction refers to a solar cell where a proportion of the junction area is substantially parallel to the longest axis of the elongate nanostructures.

The phrase two-dimensional array refers to an arrangement of the elongate nanostructures in a plane parallel to the supporting substrate. For example, the two-dimensional array may include a periodic lattice such that it can be described by a repeating unit cell, for example, cubic or hexagonal. Alternatively, the array may include a quasi-periodic lattice with mild, random displacement (chirping) of the positions of the elongate structures from periodic lattice points. Alternatively, the array may include a random arrangement of the elongate nanostructures on the substrate.

The phrase elongate nanostructure refers to a structure with at least one of the horizontal dimensions smaller than the vertical dimension by a ratio of at least 2:1 and with at least one horizontal dimension less than 1 um and preferably less than 100 nm, and where the vertical dimension is greater than 100 nm and preferably greater than 1 um.

The phrase substantially vertical in the context of the elongate nanostructures refers to an orientation of the longest axis within 15 degrees of the normal to the plane of the supporting substrate.

The phrase average pitch, p, refers to the average centre-to-centre spacing of elongate nanostructures and is defined as:

p=1/\sqrt{D}

where D is the average number of elongate nanostructures per unit area. For periodic structures, p is equal to the distance between nearest neighbor elongate nanostructures.

The term close-packed refers to a nanostructured solar cell where the average pitch of the elongate structures is equal to or less than twice the total thickness of the solar cell layers formed over the elongate nanostructures.

The term non-close-packed refers to a nanostructured solar cell where the average pitch of the elongate structures is greater than twice the total thickness of the solar cell layers formed over the elongate nanostructures such that the spacing between the top surface of the active region running parallel to the major axis of the elongate nanostructures is greater than zero, and preferably greater than 10 nm, and still further preferably greater than 100 nm.

The advantages of the nanostructured solar cell structure and method in accordance with the present invention include the following:
The present invention has greater compatibility with conventional thin film solar cell production processes and equipment since high deposition conformality is not required, unlike the requirement for a close-packed structure.
The elongate nanostructure can be lengthened to independently increase the effective optical path length of the cell to absorb wavelengths with a low absorption coefficient.
The thickness of the active region can be reduced to increase the carrier extraction efficiency.
The surface of the nanostructured solar cell has a moth-eye structure that creates a refractive index gradient with broadband reflection properties
The average refractive index of the vertical junction region of the cell is intermediate between the surrounding medium and the active region. This further reduces reflections at the cell-air interface.
Periodicity of the elongate nanostructured array creates a photonic crystal-like structure which is capable of exceeding the conventional 4n² optical path length enhancement factor limit associated with a randomizing (also commonly referred to as a “Lambertian”) surface.

Accordingly, an aspect of the invention is a photovoltaic device. In an exemplary embodiment, the photovoltaic device includes a substrate, a two-dimensional array of elongate nanostructures extending substantially perpendicularly from a surface of the substrate, and a thin film solar cell disposed over the nanostructures such that the thin film solar cell substantially conforms to the topography of the nanostructures. An average separation of nearest neighbor solar cell coated nanostructures is greater than zero and less than a vacuum wavelength of light corresponding to a band gap of absorption of the thin film solar cell.

In another exemplary embodiment of the photovoltaic device, the thin film solar cell comprises an active region that conforms to the elongate nanostructures.

In another exemplary embodiment of the photovoltaic device, the thin film solar cell further comprises a first electrode that conforms to a surface of the active region.

In another exemplary embodiment of the photovoltaic device, a separation of opposing outer surfaces of the first electrode extending along adjacent elongate nanostructures is greater than zero and less than the vacuum wavelength of the light corresponding to the band gap of the active region.

In another exemplary embodiment of the photovoltaic device, the thin film solar cell further comprises a second electrode that is an electrically conductive film between the active region and the substrate.

In another exemplary embodiment of the photovoltaic device, the substrate is a second electrode made of an electrically conductive material.

In another exemplary embodiment of the photovoltaic device, the average separation between coated nearest neighbor elongate nanostructures is greater than 10 nm.

In another exemplary embodiment of the photovoltaic device, the average separation between coated nearest neighbor elongate nanostructures is greater than 100 nm.

In another exemplary embodiment of the photovoltaic device, a length of the elongate nanostructures is greater than an effective absorption depth of the active region.

In another exemplary embodiment of the photovoltaic device, the arrangement of the two-dimensional array of elongate nanostructures is periodic.

In another exemplary embodiment of the photovoltaic device, the arrangement of the two-dimensional array of elongate nanostructures is quasi-periodic.

In another exemplary embodiment of the photovoltaic device, the arrangement of the two-dimensional array of elongate nanostructures is random.

In another exemplary embodiment of the photovoltaic device, the substrate and the elongate nanostructures are transparent over the spectral response range of the device.

In another exemplary embodiment of the photovoltaic device, the elongate nanostructures are electrically conductive.

In another exemplary embodiment of the photovoltaic device, the elongate nanostructures form part of a semiconductor junction of the active region.

In another exemplary embodiment of the photovoltaic device, the active region is a multijunction active region.

In another exemplary embodiment of the photovoltaic device, the active region includes amorphous silicon.

In another exemplary embodiment of the photovoltaic device, a medium between the coated nearest neighbor nanostructures has a refractive index lower than the active region of the solar cell.

In another exemplary embodiment of the photovoltaic device, the elongate nanostructures are formed integrally with the substrate.

Another aspect of the invention is a method of making a photovoltaic device. In an exemplary embodiment, the method includes forming a substrate, forming a two dimensional array of elongate nanostructures extending substantially perpendicularly from a surface of the substrate, and disposing a thin film solar cell over the nanostructures such that the thin film substantially conforms to the topography of the nanostructures. An average separation of nearest neighbor solar cell coated nanostructures is greater than zero and less than a vacuum wavelength of light corresponding to a band gap of absorption of thin film solar cell.

In another exemplary embodiment of the method of making a photovoltaic device, the thin film solar cell is formed by forming an active region that conforms to the elongate nanostructures.

In another exemplary embodiment of the method of making a photovoltaic device, the thin film solar cell is further formed by forming a first electrode that conforms to a surface of the active region.

In another exemplary embodiment of the method of making a photovoltaic device, a separation of opposing outer surfaces of the first electrode extending along adjacent elongate nanostructures is greater than zero and less than the vacuum wavelength of the light corresponding to the band gap of the active region.

In another exemplary embodiment of the method of making a photovoltaic device, the thin film solar cell is further formed by forming a second electrode that is an electrically conductive film between the active region and the substrate.

In another exemplary embodiment of the method of making a photovoltaic device, the substrate is a second electrode made of an electrically conductive material.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1 is a schematic view of part of a horizontal junction solar cell.

FIG. 2 is a schematic view of part of a vertical junction solar cell

FIG. 3 is a schematic view of a close-packed vertical junction nanostructured solar cell.

FIG. 4 is a scanning electron micrograph showing a cross-sectional image of an array of elongate nanostructures coated with a 250 nm thick layer of hydrogenated amorphous silicon (a-Si:H).

FIG. 5 is a schematic view of a non-close-packed vertical junction nanostructured solar cell.

FIG. 6 is a three-dimensional schematic view of a p-i-n junction amorphous silicon vertical junction nanostructured solar cell.

FIG. 7 is a graph of short circuit current density (Jsc) and open circuit voltage (Voc) versus first electrode separation.

FIG. 8 is a graph of efficiency versus first electrode separation.

FIG. 9 is a schematic view of a non-close-packed vertical junction nanostructured solar cell with illumination through a transparent substrate.

FIG. 10 is a series of schematic views of multiple arrangements of a two-dimensional array of elongate nanostructures.

FIG. 11 is a schematic view of a vertical junction nanostructured solar cell with non-conformal deposition of the active region and first electrode.

FIG. 12 is a schematic view of a multijunction vertical junction nanostructured solar cell.

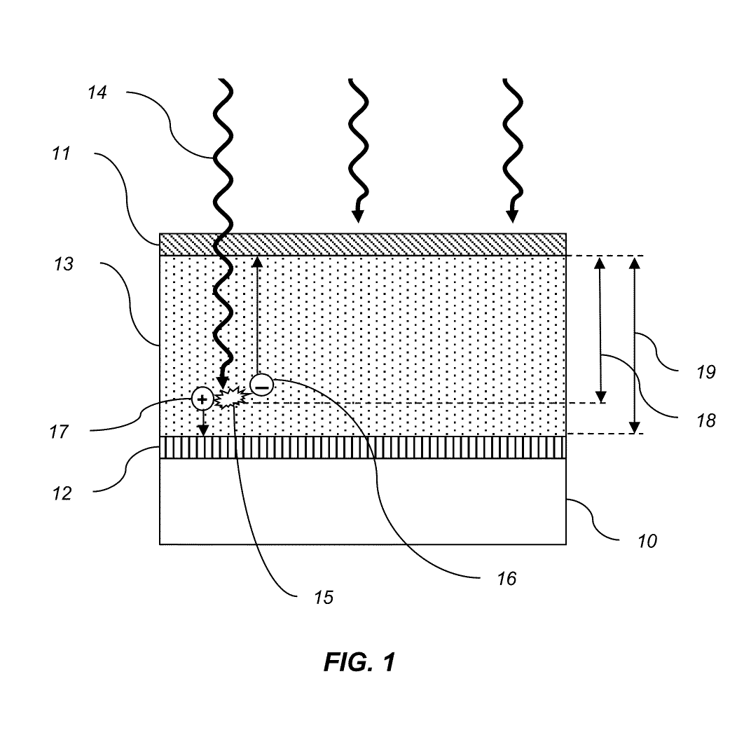

### DESCRIPTION OF REFERENCE NUMERALS

10. Substrate
11. First electrode
12. Second electrode
13. Active region
14. Incident photon path
15. Photon absorption/carrier generation event
16. Electron migration path to first electrode
17. Hole migration path to second electrode
18. Photon path length before absorption and maximum carrier extraction length
19. Thickness of active region
20. Substrate
21. First electrode
22. Second electrode
23. Active region
24. Incident photon path
25. Photon adsorption/carrier generation event
26. Electron migration to first electrode
27. Hole migration to second electrode
28. Height of the active region
29. Thickness of active region
30. Substrate
31. First electrode
32. Elongate nanostructures
33. Active region
34. Incident photon path
35. Average pitch of elongate nanostructures
36. Moth-eye plane with graded refractive index from surrounding transparent medium
37. Vertical junction region with long optical path length and intermediate refractive index.
38. Low refractive index surrounding medium (air, polymer etc)
39. Thickness of active region
40. Substrate
41. Amorphous silicon disposed over elongate nanostructures
42. Trapped void due to non-conformal deposition
43. Width of void at base of elongate nanostructures
44. Pitch of elongate nanostructures
45. Moth-eye plane with graded refractive index from surrounding transparent medium
46. Vertical junction region with long optical path length and intermediate average refractive index.
50. Substrate
51. First electrode
52. Elongate nanostructures
53. Active region
54. Incident photon path
55. Average pitch of elongate nanostructures
56a. Moth-eye plane with graded refractive index from surrounding transparent medium
56b. Vertical junction region with long optical path length and intermediate refractive index
56c. Horizontal junction region of active region with high refractive index
57. Separation of first electrode surfaces
58. Low refractive index surrounding medium (air, polymer etc)
59. Unit cell of lattice
60. Nanostructured substrate
61. Aluminium (Al) layer
62. Aluminium zinc oxide (AZO) layer
63. Hydrogenated amorphous silicon (a-Si:H) n-i-p junction
64. Indium tin oxide (ITO) layer
65. Elongate structures
66. Thin film solar cell layers
70. Maxima in short circuit current density
71. Region of maximum open circuit voltage
90. Substrate
91. First electrode
92. Elongate nanostructures
93. Active region
94. Incident photon path
100. Substrate
101. Elongate nanostructures
102. Plane of the substrate
103. Cubic arrangement of elongate nanostructures projected in the plane of substrate
104. Hexagonal arrangement of elongate nanostructures projected in the plane of substrate
105. Quasi-random or chirped cubic arrangement of elongate nanostructures projected in the plane of substrate
106. Random arrangement of elongate nanostructures projected in the plane of substrate
110. Substrate
111. First electrode with non-conformal coverage
112. Elongate nanostructures
113. Active region with non-conformal coverage
114. Incident photon path
115. Thickness of active region at top of elongate nanostructures
116. Thickness of active region at bottom of elongate nanostructures
120. Substrate
121. First electrode
122. Elongate nanostructures
123a Active region (first semiconductor junction)
123b Active region (second semiconductor junction)
124 Incident photon path

### DETAILED DESCRIPTION OF INVENTION

To facilitate the understanding of the present invention, reference will now be made to the appended drawings of embodiments.

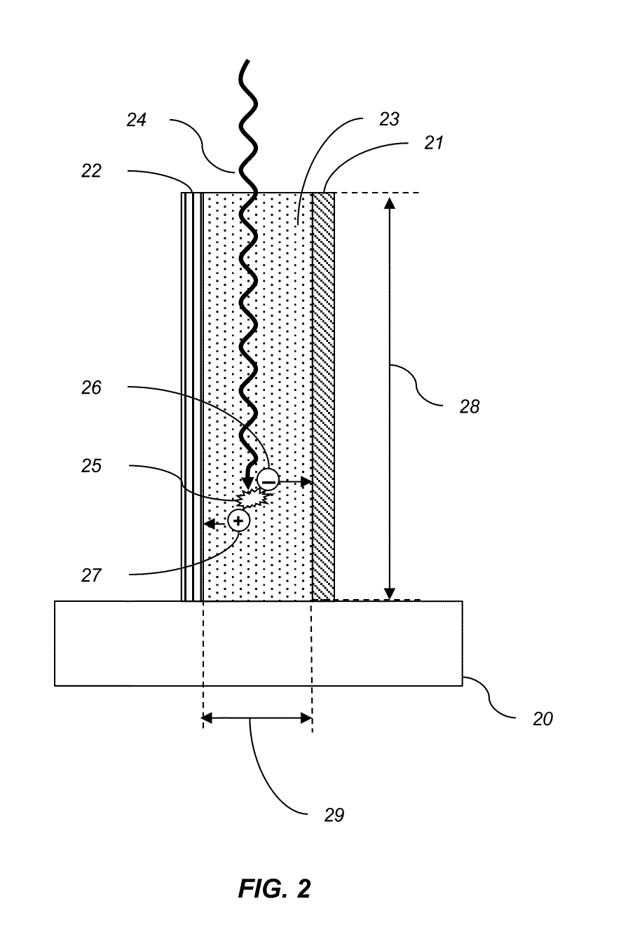

FIG. 2 schematically illustrates a vertical junction solar cell in which the layers of a first electrode 21, second electrode 22 and active region 23 of the cell lie in a plane normal to the plane of a substrate 20. In this configuration, the incident photon path 24 is perpendicular to the electron 26 and hole 27 migration paths to the first and second electrode respectively. In contrast to the conventional horizontal junction described above, in the vertical junction solar cell of FIG. 2 the length scales over which photons are absorbed and carriers are extracted are substantially independent from one another. That is, effective thickness of the portion of the active region available for absorption is determined by the extent of the vertical dimension 28 of the active region 23, and the distance over which a carrier must travel before being collected by either the first or second electrode is determined by the thickness 29 of the active region 23.

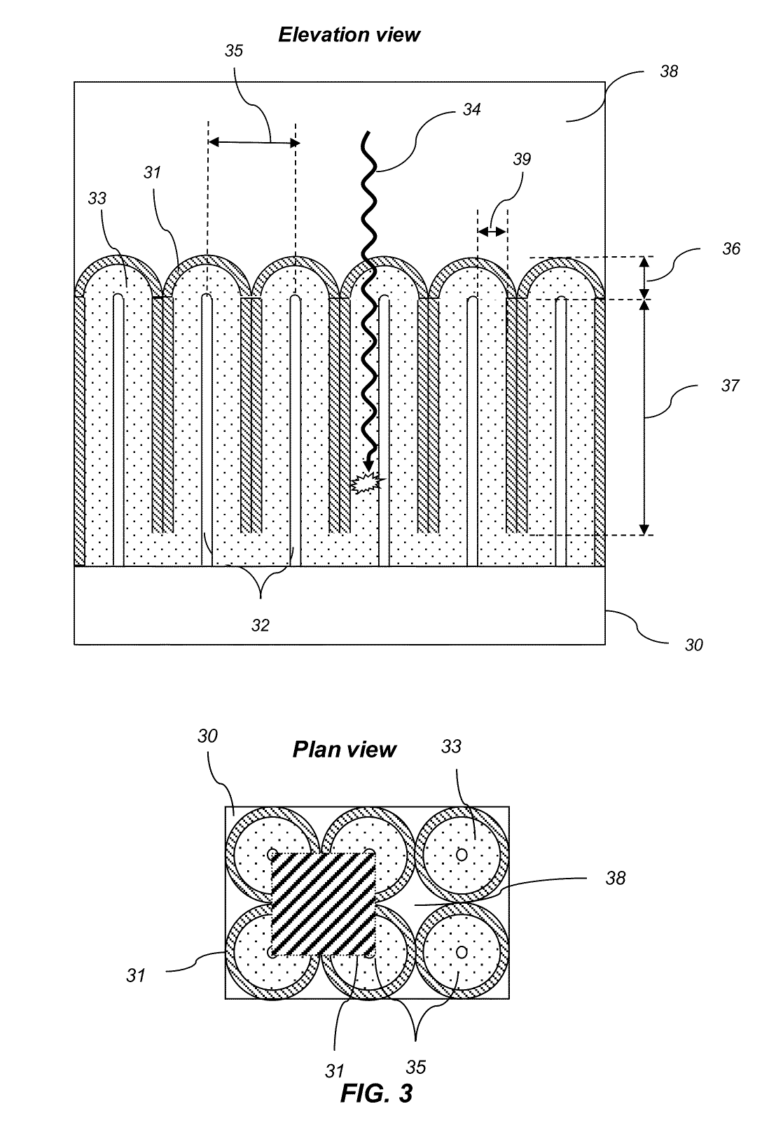

FIG. 3 schematically illustrates a close-packed vertical junction nanostructured solar cell. The solar cell includes at least a substrate 30 upon which there is formed: a two dimensional array of elongate nanostructures 32 extending substantially vertically from the top surface of the substrate; an active region 33; and a first electrode 31 disposed substantially conformally over the elongate nanostructures. A second electrode (not shown) may exist at the opposite interface of the active region to first electrode. The volume of the solar cell has at least three distinct regions in the plane of the substrate. A top surface region 36 includes an array of domed features around the ends of the elongate nanostructures and may be surrounded by a low refractive index medium 38. A vertical junction region 37 is formed along the length of the elongate nanostructures and has an intermediate refractive index. The base of the nanostructures has the highest refractive index. In the close-packed structure of FIG. 3, the separation of the first electrode surfaces in the vertical junction region is preferably zero or as close to zero as possible. This is achieved by selection of appropriate values of the diameter and pitch 35 of the elongate nanostructures, a thickness 39 between the elongate nanostructures and the first electrode, and the thicknesses of the first electrode and the second electrode.

An advantage of a close-packed arrangement such as the one shown in FIG. 3 is that it maximizes the junction area while permitting the separation of the electrodes, determined by the active region thickness, to be minimized.

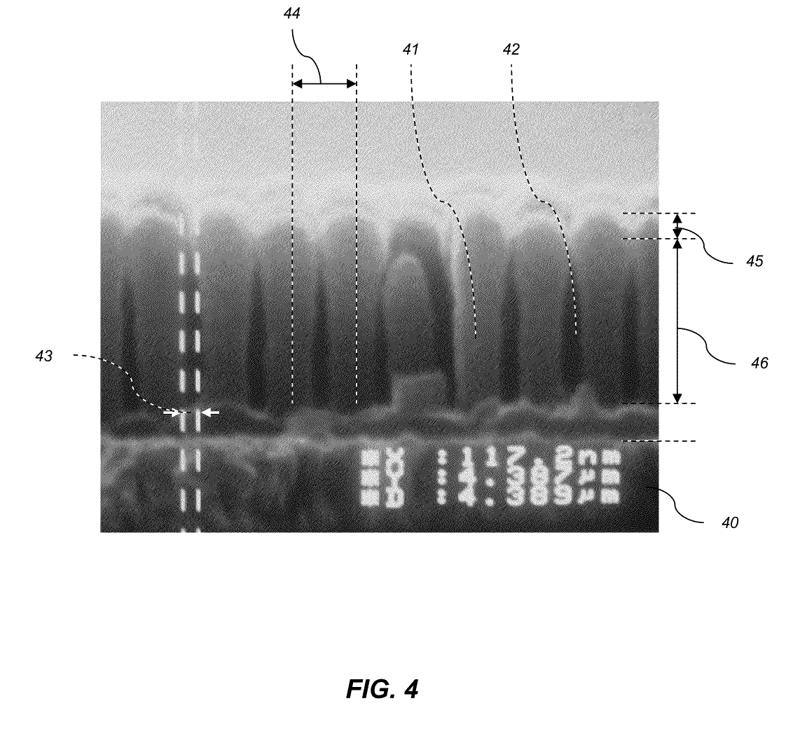

A close-packed configuration commonly is utilized in an attempt to maximize the solar cell efficiency. However, fabrication of substantially close-packed nanostructured solar cells is extremely challenging using deposition techniques commonly employed for the manufacture of thin film solar cells. For example, common techniques include plasma enhanced chemical vapor deposition and sputter deposition. These techniques do not exhibit sufficient deposition conformality, which results in the inclusion of voids within the film and discontinuous electrode layers. FIG. 4 shows a cross-section of a cubic lattice nanostructured substrate 40 including elongate nanostructures with 50 nm diameter, 1.5 um length and 500 nm pitch 44, coated with 250 nm of amorphous silicon 41 by PECVD. It can be seen that although the volume between the elongate nanostructures is filled at their tips, there are voids 42 approximately 100 nm wide 43 toward the base of the elongate nanostructures. Filling of the volume between the nanostructures is limited, for example, by the low surface mobility of the deposited precursor species and the low pressure of the deposition process. The corresponding surface moth-eye 45 and vertical junction 46 regions are also indicated in FIG. 4.

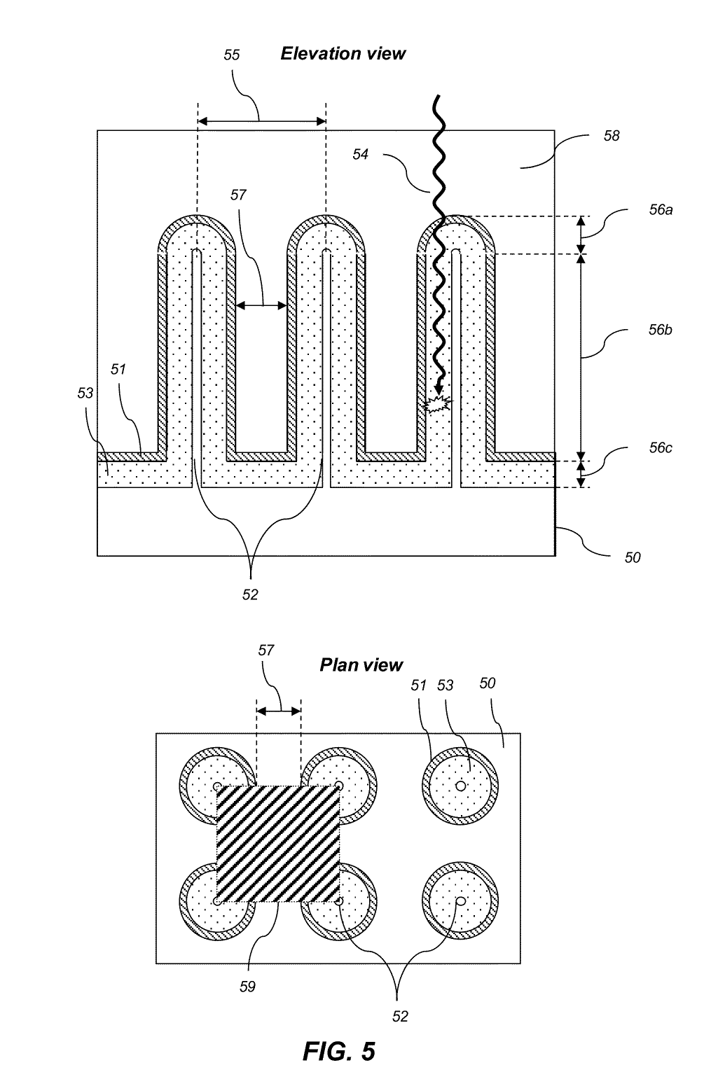

As described above, a close-packed configuration commonly is utilized in an attempt to maximize the solar cell efficiency. However, fabrication of substantially close-packed nanostructured solar cells is extremely challenging using deposition techniques commonly employed for the manufacture of thin film solar cells. In this vein, undesirable voids occur between the elongate nanostructures, particularly about the bases of the elongate nanostructures (see FIG. 4 as referenced above). To avoid such deficiencies, the present invention provides a non-close-packed vertical junction nanostructured solar cell. An exemplary embodiment of a non-close-pack vertical junction nanostructured solar cell in accordance with the present invention is shown in FIG. 5. The configuration of FIG. 5 is exemplified by the following:
The separation 57 between opposing outermost surfaces of the first electrode 51 conforming to an active region 53 coated nearest neighbor elongate nanostructures 52 is selected from the range greater than zero and less than a length corresponding to the vacuum wavelength of the band gap of the thin film solar cell, as particularly determined by the absorber material within the active region. Within this range there exists at least one preferred or optimum value for the separation yielding at least one maximum value of Jsc.
The lower limit of the separation is determined by the degree of deposition conformality and is preferably less than 500 nm, further preferably less than 200 nm, still further preferably less than 100 nm and still further preferably less than 10 nm.
The length of the vertical elongate nanostructures is selected to be substantially similar to or greater than the effective absorption depth of the active region. The effective absorption depth is approximately given by the product of the volume fraction of the active region within the unit cell 59 of the lattice of vertical elongate nanostructures and absorption coefficient of the absorber material of the active region.
The open circuit voltage of the non-close-packed vertical junction nanostructured solar cell is greater than the open circuit of the equivalent close-packed vertical junction nanostructured solar cell.
The upper surface region 56a of the nanostructured cell includes a domed profile, commonly known in the art as a “moth-eye”-type structure, that creates a graded refractive index interface between the surrounding medium 58 of the cell and exhibits broadband antireflection properties for the incident light.
The effective refractive index of the vertical junction region 56b, n_{vertical}, is intermediate between a low refractive index surrounding medium, n_{filler}, and the high index base active region 56c, n_{active}. The effective refractive index is determined by the volume fraction of the unit cell of the lattice of vertical elongate nanostructures 52 occupied by each of the layers. n_{vertical} can be controlled according to the pitch 55 between nanostructures, the arrangement of the nanostructures and the dimensions (for example, thickness) of the component material layers. The intermediate refractive index further reduces reflections from the nanostructured cell and is optimum when equal to the geometric mean of the filler medium and the base active region. That is, when:

n_{vertical}=\sqrt{n_{filler}n_{active}}
The value of n_{vertical} is preferably selected to be substantially close to the optimum value.
The present invention includes a two-dimensional periodic structure of high and low refractive index regions forming a photonic crystal structure that can achieve an absorption enhancement factor that exceeds the conventional limit for an ideal randomizing surface, commonly referred to in the art as a Lambertian surface.
The present invention is compatible with conventional thin film deposition methods such as plasma enhanced chemical vapor deposition and physical deposition. As such, the minimum first electrode 51 separation 57 should preferably be greater than 1 nm, further preferably greater than 10 nm and still further preferably greater than 100 nm.

The present invention thus provides an optimum average nanostructure pitch 52 and first electrode separation 57 constituting a non-close-packed arrangement that provides higher solar cell efficiency as compared to conventional close-packed arrangements.

The present invention uses the combination of efficient light trapping and uniform carrier generation that is achieved in non-close packed nanostructured thin films to achieve enhancement of both the short circuit current density Jsc and open circuit voltage Voc of the cell to a greater extent than can be achieved using a conventional close-packed structure. The power conversion efficiency of the cell η is given by:

η=J_{sc}V_{oc}FF

where FF is the fill factor. Thus, η is correspondingly increased by the configuration of the present invention.

Improvement to the short circuit current density Jsc of the nanostructured cell of the present invention is achieved by increased absorption over the spectral response range of the cell. Increased absorption is achieved by reduction of reflection losses and an increased effective optical path length in the active region through light trapping within a periodic or quasi-periodic structure.

The reflectivity of a solar cell in accordance with the present invention depends on the average pitch of the elongate nanostructures and the surface profile of the overlying solar cell, and includes one or more minima.

The optical path length can, for example, be increased by increasing the vertical thickness of the active region or by trapping light in the active region. The absorption of the cell is characterized by its absorptance A and is given by the Beer-Lambert law:

A=1−e^{-αX}

where α is the absorption coefficient of the active region of the solar cell and X is the optical path length in the active region.

Improvement to the open circuit voltage Voc is achieved by reduced charge carrier recombination. For a given material, charge carrier recombination is reduced by decreasing the transit time or transit length required to reach the electrical contacts. In accordance with the present invention, this is achieved by reducing the distance between the contacts and/or minimizing potential gradients perpendicular to the shortest distance between the contacts. For example, the effective optical density of a cell in accordance with the present invention depends on the average pitch of the nanostructures and determines both the carrier concentration gradient extending along the length of the nanostructures and total absorptance of the cell. In other words, the effective optical density depends on the absorption coefficient and the volume fraction occupied by the individual materials comprising the vertical junction region. In addition, the thickness of the solar cell layers determines the distance between the contacts.

The combination of these effects means that within the range described herein there exists at least one preferred or optimum average pitch that affords higher efficiency. An aspect of the present invention is that the dimensions of the structure are selected such that both technical effects optimum pitch and higher efficiency are achieved.

### First Embodiment

In a first embodiment of the present invention, shown in FIG. 5 in both an elevation and a plan view, a vertical junction nanostructured thin film solar cell includes a substrate 50 upon which there is formed a two dimensional array of elongate nanostructures 52 extending substantially vertically from a top surface of the substrate. The elongate nanostructures may be formed as a separate layer or component, or the elongate nanostructures may be fashioned integrally with or from the substrate itself. For example, the elongate nanostructures may be fashioned by removing material from the top surface of the substrate. In such case the nanostructures can be considered to be integral to the substrate rather than distinct features formed on or added to the substrate.

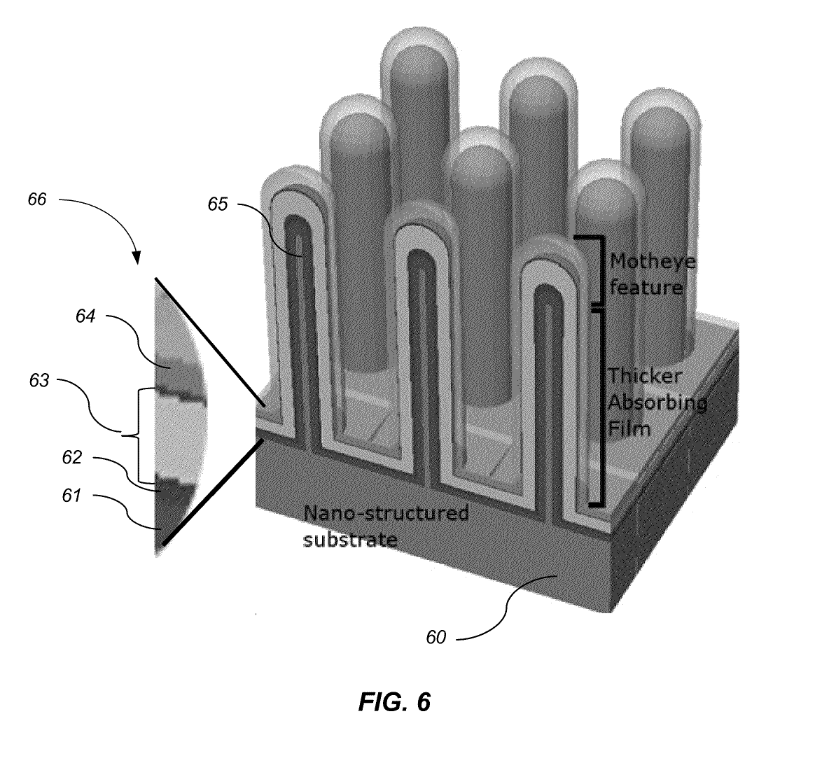

The solar cell structure further includes a thin film solar cell disposed over the elongate nanostructures such that the thin film solar cell substantially conforms to the topography of the nanostructures. The thin film solar cell includes a second electrode (see FIG. 6 below), an active region 53 that conforms to the elongate nanostructures and includes at least one junction, and a first electrode 51 that conforms to the surface of the active region. The elongate nanostructures have an average separation of nearest neighbor solar cell coated nanostructure, depicted in FIG. 5 as an average pitch 55, that is greater than zero and less than a vacuum wavelength of light corresponding to a band gap of absorption of the thin film solar cell. In exemplary embodiments, the average separation between coated nearest neighbor elongate nanostructures is greater than 10 nm, and may be greater than 100 nm.

As depicted in FIG. 5, the average pitch 55 is configured such that the separation 57 of opposing outer surfaces of the first electrode extending along adjacent elongate nanostructures is greater than zero and less than the vacuum wavelength of the light corresponding to the band gap of the active region. Light 54 is incident on the top surface of the solar cell. The substrate may function as the second electrode if it is electrically conductive. Alternatively, the second electrode may be formed as an electrically conductive thin film between the active region 53 and the substrate 50. The second electrode, like the active region 53 and first electrode 51, may also coat the elongate nanostructures 52. The elongate nanostructures 52 themselves may be electrically conductive.

To maximize the solar cell efficiency, the first electrode separation 57 is selected within the range greater than zero and less than the lowest bandgap of the active region. More specifically, the separation is selected to maximize both the short circuit current density (Jsc) and the open circuit voltage (Voc). The length of the elongate nanostructures is selected from the range greater than the effective absorption depth of the nanostructured solar cell with the given first electrode separation

In one non-limiting example, shown in FIG. 6, the vertical junction nanostructured thin film solar cell 66 is a hydrogenated amorphous silicon (a-Si:H) thin film solar cell including of a plurality of layers disposed on a nanostructured substrate 60 having a cubic unit cell, wherein said layers include, from bottom to top: a second electrode of aluminum 61 with a thickness of 100 nm and aluminum zinc oxide (AZO; 30 nm) 62; an active region 63 comprising a p-i-n junction of n-type amorphous silicon (20 nm), intrinsic amorphous silicon (100 nm), p-type amorphous silicon (10 nm); and a transparent first electrode 64 of indium tin oxide (ITO; 70 nm). The length and diameter of the elongate nanostructures 65 is 1.5 um and 50 nm respectively.

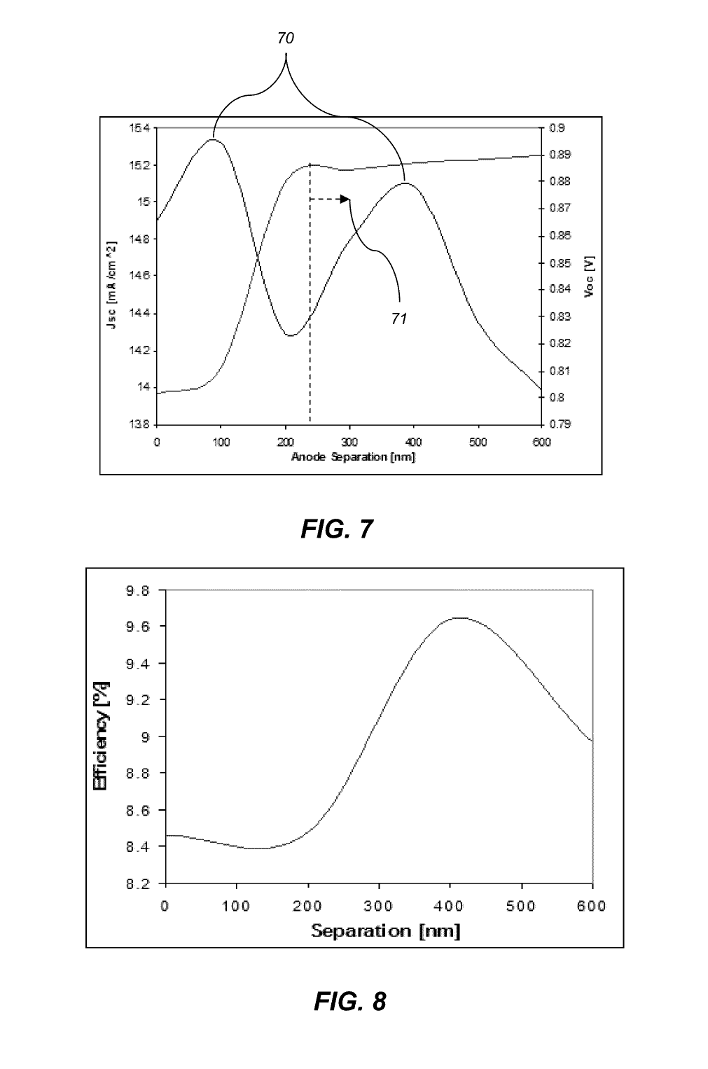

FIG. 7 shows the corresponding short circuit current density (Jsc) and open circuit voltage (Voc) as a function of the first electrode separation for a vertical junction nanostructured hydrogenated amorphous silicon (a-Si:H) p-i-n solar cell in accordance with embodiments of the present invention. The first electrode separation was varied by changing the pitch of the elongate nanostructures while keeping the solar cell layer thicknesses the same. The Jsc curve exhibits two maxima 70 corresponding to reflection minima for the periodic lattice of thin film coated elongate nanostructures. Both maxima exist for a first electrode separation greater than that required to form a close-packed structure. The Voc curve exhibits a step function-type profile including two plateaus, wherein the higher Voc plateau of the two exists for an electrode separation greater than 200 nm 71.

FIG. 8 shows the efficiency of the nanostructured solar cell in accordance with embodiments of the present invention, which is proportional to the product of Voc and Jsc, shown in FIG. 7. The combination of the plateau in Voc and the maxima in Jsc leads to an optimum value for the solar cell efficiency approximately coinciding with the second maximum in the Jsc.

The position of the maximum in cell efficiency is dependent on several parameters, such as, for example, the thickness of the individual layers of the solar cell, the first electrode separation, the pitch and dimensions of the elongate nanostructures. In general, the solar cell efficiency as a function of first electrode separation is shown in FIG. 8 where the intermediate first electrode separation is in the range greater than zero and less than the vacuum wavelength corresponding to the smallest bandgap in the active region.

According to the present invention, the vertical junction nanostructured solar cell may include any of the following features:

The first electrode is substantially transparent over the spectral response range of the active region.

If desired, one or more encapsulating layers or antireflection coatings may be formed over the solar cell at the interface between the first electrode and the filler medium.

The length of the elongate structures and correspondingly the height of the vertical junction of the active region may be greater than the thickness of the active region layer(s) in an equivalent planar thin film solar cell of the same type. In other words, a length of the elongate nanostructures may be greater than the effective absorption depth of the active region. For example, in the case that the thin film solar cell type includes an amorphous silicon p-i-n junction, the thickness of the vertical junction region may be greater than 400 nm. If desired, the length of the nanostructures can be increased to maximize the absorption of wavelengths with low absorption coefficient.

By virtue of the increased light trapping in a structure in accordance with the present invention, the thickness of the active region may be less than the thickness required for an equivalent conventional planar thin film solar cell of the same type, thereby enabling better carrier extraction. For example, in the case that the thin film solar cell type includes an amorphous silicon p-i-n junction, the thickness may be less than 400 nm, and preferably less than 300 nm and still further preferably less than 200 nm, and yet still further preferably less than 100 nm.

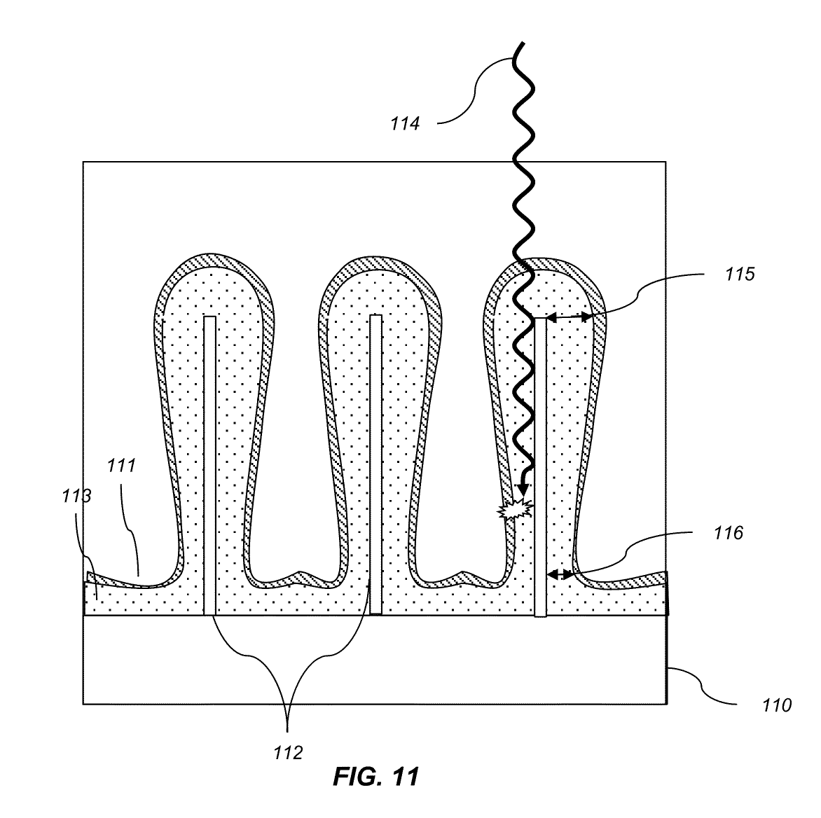

It is noted that the thickness of the thin film solar cell formed over the substrate including the elongate nanostructures may vary based on, for example, the method used to form the thin film solar cell. For example, the thickness of the thin film solar cell extending along the elongate nanostructures may be thinner than that extending along the horizontal surface of the substrate. An alternative example as shown in FIG. 11 includes a substrate 110, first electrode 111, elongate nanostructures 112, and an active region 113, with the incident photon path depicted as 114. In this embodiment of FIG. 11, the thickness of the thin film solar cell may be greater at the top of the elongate nanostructures 115 than at the bottom 116. In an alternative example (not shown), the thickness of the thin film solar cell may be greater at the bottom of the elongate nanostructures than at the top. Variations in thin film thickness can arise due to lack of conformality in the thin film deposition process. Examples of such deposition processes include chemical vapour deposition and solution deposition.

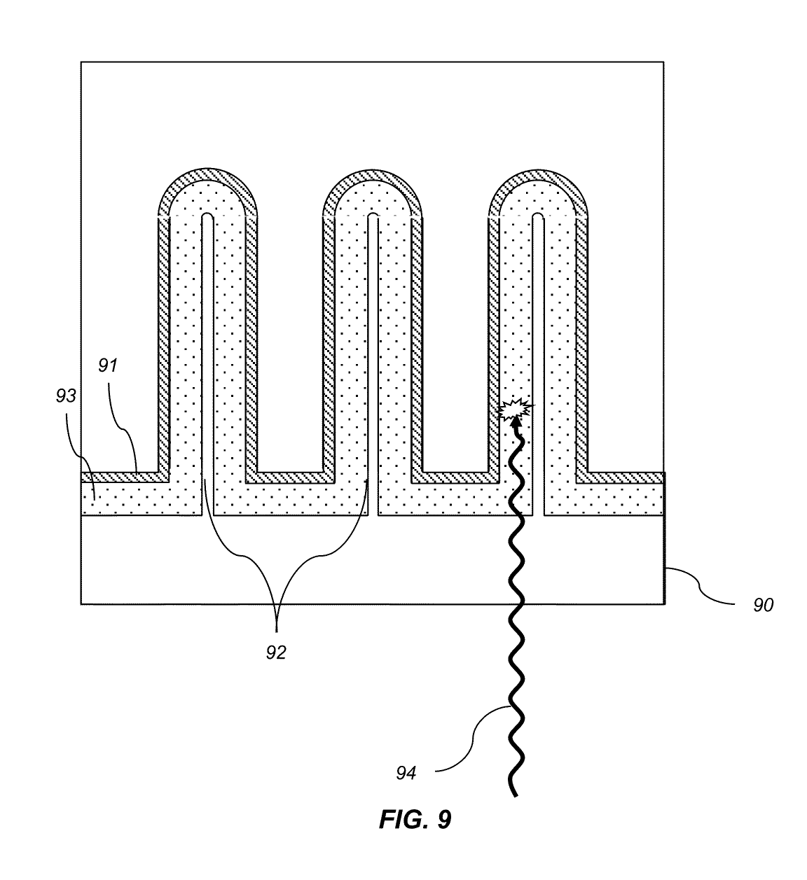

Referring to the alternative embodiment of FIG. 9, if desired the substrate 90 may be substantially transparent (>80%) over the solar spectrum region of interest or spectral range of the device. The substrate, for example, may be glass or opaque metal. Alternatively, the substrate may be translucent or scattering, or employ other techniques that increase the absorption of light in the active region 93. For example, such techniques may include plasmonic structures (e.g. metal nanostructures), diffractive structures (e.g. gratings or photonic crystals), or refractive structures (e.g. microlenses) as are known in the art. The elongate nanostructures 91 also may be transparent over the spectral response range of the device

Referring again to FIG. 5, the surrounding medium 58 between adjacent surfaces of the nanostructured solar cell may be any material that is substantially transparent over the spectral response range of the solar cell. Preferably, the filler medium should have a refractive index that is lower than the refractive index of the adjacent layers of the thin film solar cell. For example, the filler medium may include air, silica, ethylvinyl acetate etc.

The thin film solar cell may have a rounded or domed profile at the tips of the elongate nanostructures. This has the effect of creating a graded refractive index profile, commonly referred to as a moth-eye structure, which has broadband antireflection properties.

The thin film solar cell may include at least one semiconductor junction type. For example, the junction(s) may include a p-n junction, p-i-n junction, or Schottky junction.

The thin film solar cell may include any type of thin film solar cell material. Examples of possible types of thin film solar cells that may be used in accordance with the present invention include those based on amorphous silicon (a-Si), amorphous silicon-germanium (a-SiGe), amorphous germanium (a-Ge), amorphous silicon carbide (SiC), micro- or nanocrystalline silicon (uc-Si), cadmium telluride (CdTe), copper indium gallium sellenides or sulfides (CIGS), Copper Zinc Tin Sulfide (CZTS), organic or polymer materials, colloidal quantum dot materials.

### Second Embodiment

In a second embodiment, a vertical junction nanostructured thin film solar cell may be formed by a process of: 1) forming a substrate, 2) forming a two dimensional array of elongate nanostructures extending substantially perpendicularly from a surface of the substrate; and 3) disposing a thin film solar cell over the nanostructures such that the thin film substantially conforms to the topography of the nanostructures using a process that may be of any suitable type including, hydrogenated amorphous silicon (a-Si:H), microcrystalline silicon (uc-Si), cadmium telluride (CdTe), copper indium gallium sellenide or sulfide (CIGS), organic or polymer materials, or colloidal quantum dots.

### Third Embodiment

In a third embodiment, the elongate nanostructures are formed on a substrate by, in one case, an additive method such as a one-dimensional growth method, for example, metal catalysed vapor-liquid-solid (VLS) growth, or solid-liquid-solid (SLS) growth. In another variation, the elongate nanostructures are formed by a subtractive method such as masking and etching of the substrate. In yet another variation, the elongate nanostructures are formed by a combination of an additive and subtractive methods such as layer deposition followed by masking and etching of the layer.

### Fourth Embodiment

In a fourth embodiment as shown in FIG. 9, the nanostructured solar cell is designed such that light is intended to be incident, as indicated by reference numeral 94, through the support substrate 90. In this embodiment the elongate nanostructures 92 function as the low refractive index filler medium, and the first electrode is formed over the elongate nanostructures followed by the active region 93 and the second electrode 91. The substrate is substantially transparent, for example, preferably greater than 80%, over the spectral response range of the solar cell.

### Fifth Embodiment

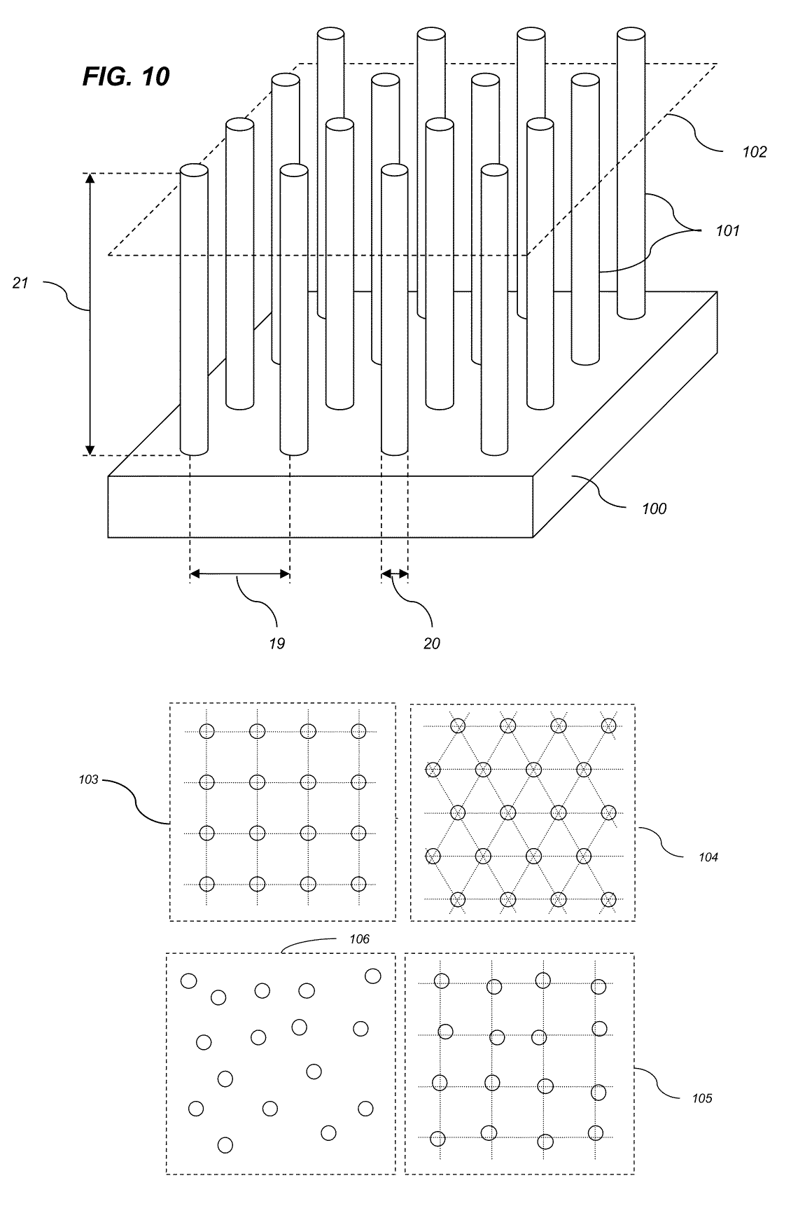

In a fifth embodiment shown in FIG. 10, the elongate nanostructures 101 may have any periodic, quasi-periodic or random arrangement in the plane 102 of the substrate 100. For example, variations of the arrangement of the nanostructures may include a periodic cubic 103 or hexagonal 104 arrangement, or quasi-periodic cubic 105 and random 106 arrangements.

### Sixth Embodiment

In a sixth embodiment the elongate nanostructures may perform an active or passive function within the device. For example, passive function may include the elongate nanostructures acting primarily as a structural support on which the thin film solar cell is formed. In another example, an active function may include the elongate nanostructures acting as an electrical contact, for example the second electrode, or an optical waveguide.

### Seventh Embodiment

In a seventh embodiment the elongate nanostructures may have at least one of the horizontal dimensions smaller than the vertical dimension by a ratio of at least 2:1, and at least one horizontal dimension less than 1 um and preferably less than 100 nm, and a the vertical dimension greater than 100 nm and preferably greater than 1 um.

### Eighth Embodiment

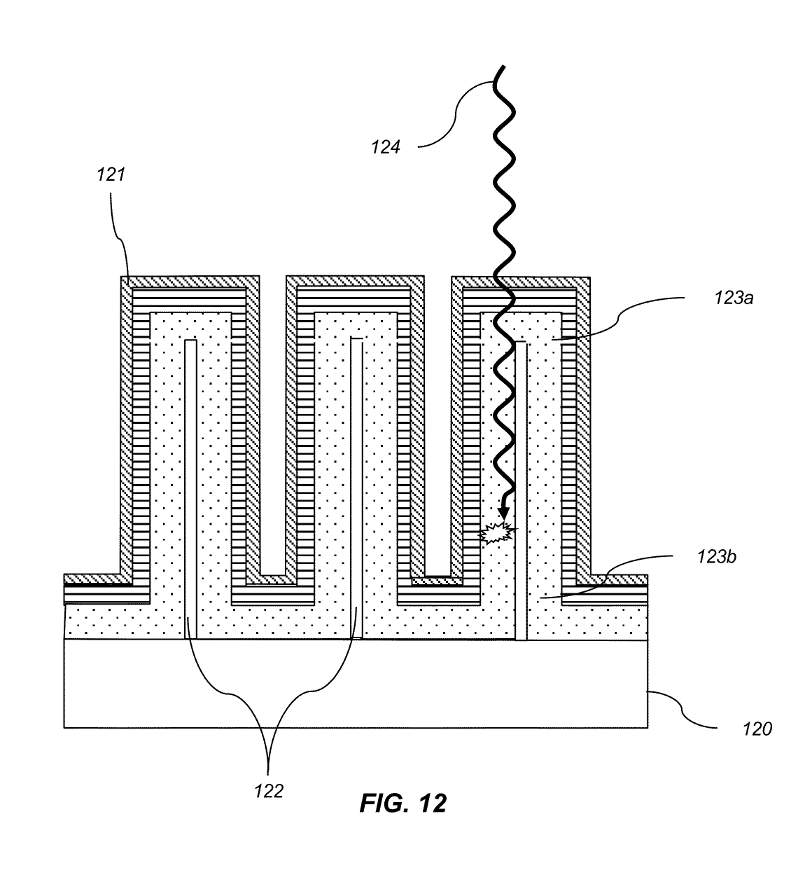

In an eighth embodiment shown in FIG. 12, a nanostructured solar cell may include a substrate 120, a first electrode 121, and elongated nanostructures 122, with the incident light path being depicted by element 124. The thin film solar cell may comprise at least a first 123a and second 123b photovoltaic semiconductor junction (active region) formed on top of one another. Each of said junction may be designed to operate with enhanced efficiency over a different range of the incident light spectrum. For example, a microcrystalline silicon junction and an amorphous silicon junction may be employed. Alternatively, the nanostructured thin film solar cell may be mechanically stacked with another semiconductor junction. Thus, the elongate nanostructures may form part of a semiconductor junction of the active region, and the active region may be a multijunction active region.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

A vertical junction nanostructured solar cell according to the present invention may be used to improve the efficiency of existing thin film solar cells.

1. A photovoltaic device, comprising:
a substrate;
a two-dimensional array of elongate nanostructures extending substantially perpendicularly from a surface of the substrate; and
a thin film solar cell disposed over the nanostructures such that the thin film solar cell substantially conforms to the topography of the nanostructures;
wherein an average separation of nearest neighbor solar cell coated nanostructures is greater than zero and less than a vacuum wavelength of light corresponding to a band gap of absorption of the thin film solar cell.

2. The photovoltaic device according to claim 1, wherein the thin film solar cell comprises an active region that conforms to the elongate nanostructures.

3. The photovoltaic device according to claim 2, wherein the thin film solar cell further comprises a first electrode that conforms to a surface of the active region.

4. The photovoltaic device according to claim 3, wherein a separation of opposing outer surfaces of the first electrode extending along adjacent elongate nanostructures is greater than zero and less than the vacuum wavelength of the light corresponding to the band gap of the active region.

5. The photovoltaic device according to claim 3, wherein the thin film solar cell further comprises a second electrode that is an electrically conductive film between the active region and the substrate.

6. The photovoltaic device according to claim 3, wherein the substrate is a second electrode made of an electrically conductive material.

7. The photovoltaic device according to claim 1, wherein the average separation between coated nearest neighbor elongate nanostructures is greater than 10 nm.

8. The photovoltaic device according to claim 7, wherein the average separation between coated nearest neighbor elongate nanostructures is greater than 100 nm.

9. The photovoltaic device according to claim 2, wherein a length of the elongate nanostructures is greater than an effective absorption depth of the active region.

10. The photovoltaic device according to claim 1, wherein the arrangement of the two-dimensional array of elongate nanostructures is periodic.

11. The photovoltaic device according to claim 1, wherein the arrangement of the two-dimensional array of elongate nanostructures is quasi-periodic.

12. The photovoltaic device according to claim 1, wherein the arrangement of the two-dimensional array of elongate nanostructures is random.

13. The photovoltaic device according to claim 1, wherein the substrate and the elongate nanostructures are transparent over the spectral response range of the device.

14. The photovoltaic device according to claim 1, wherein the elongate nanostructures are electrically conductive.

15. The photovoltaic device according to claim 2, wherein the elongate nanostructures form part of a semiconductor junction of the active region.

16. The photovoltaic device according to claim 2, wherein the active region is a multijunction active region.

17. The photovoltaic device according to claim 2, wherein the active region includes amorphous silicon.

18. The photovoltaic device according to claim 2, wherein a medium between the coated nearest neighbor nanostructures has a refractive index lower than the active region of the solar cell.

19. The photovoltaic device according to claim 1, wherein the elongate nanostructures are formed integrally with the substrate.

20. A method of making a photovoltaic device, comprising:
forming a substrate
forming a two dimensional array of elongate nanostructures extending substantially perpendicularly from a surface of the substrate; and
disposing a thin film solar cell over the nanostructures such that the thin film substantially conforms to the topography of the nanostructures;
wherein an average separation of nearest neighbor solar cell coated nanostructures is greater than zero and less than a vacuum wavelength of light corresponding to a band gap of absorption of thin film solar cell.

21. The method of making a photovoltaic device according to claim 20, wherein the thin film solar cell is formed by forming an active region that conforms to the elongate nanostructures.

22. The method of making a photovoltaic device according to claim 21, wherein the thin film solar cell is further formed by forming a first electrode that conforms to a surface of the active region.

23. The method of making a photovoltaic device according to claim 22, wherein a separation of opposing outer surfaces of the first electrode extending along adjacent elongate nanostructures is greater than zero and less than the vacuum wavelength of the light corresponding to the band gap of the active region.

24. The method of making a photovoltaic device according to claim 22, wherein the thin film solar cell is further formed by forming a second electrode that is an electrically conductive film between the active region and the substrate.

25. The method of making a photovoltaic device according to claim 22, wherein the substrate is a second electrode made of an electrically conductive material.
